(19) United States
(12) Patent Application Publication
(10) Pub. No.: US 2026/0343904 A1
(43) Pub. Date: Oct. 29, 2026

(54) SEMICONDUCTOR DEVICE AND MANUFACTURING METHOD THEREOF

(71) Applicant: SK hynix Inc., Gyeonggi-do (KR)

(72) Inventor: Heon Yong CHANG, Gyeonggi-do (KR)

(21) Appl. No.: 19/307,033

(22) Filed: Aug. 22, 2025

(30) Foreign Application Priority Data
Apr. 23, 2025 (KR) 10-2025-0052736

(51) Int. Cl. H10B 80/00; H10W 90/00; H10W 80/00

(52) U.S. Cl. CPC H10B 80/00; H10W 90/00; H10W 80/312; H10W 80/327; H10W 90/792

(57) ABSTRACT

According to embodiments of the present disclosure, a semiconductor device may include a first semiconductor structure including a peripheral circuit and a periphery bonding pad connected to the peripheral circuit, and a second semiconductor structure including a cell bonding pad bonded to the periphery bonding pad, a plurality of first wirings connected to the cell bonding pad, a plurality of spacers respectively disposed on side surfaces of the plurality of first wirings, and a first insulating layer covering side surfaces of the plurality of spacers and lower surfaces of the plurality of first wirings, and having air gaps disposed between the plurality of spacers.

### CROSS-REFERENCE TO RELATED APPLICATIONS

The present application claims priority under 35 U.S.C. 119(a) to Korean patent application number 10-2025-0052736 filed on Apr. 23, 2025, which is incorporated herein by reference in its entirety.

### BACKGROUND

### 1. Technical Field

Embodiments of the present disclosure relate to a semiconductor device and a method of manufacturing the same.

### 2. Related Art

Due to characteristics such as miniaturization, multifunctionality, and/or low manufacturing cost, memory devices have emerged as key components in the electronics industry. As the electronics industry advances, memory devices are becoming increasingly highly integrated.

As memory cells become more highly integrated, the spacing between wirings in the memory device may decrease. As the spacing between the wirings decreases, interference may occur between adjacent wirings.

### SUMMARY

The objects addressed by the embodiments of the present disclosure are not limited to those mentioned herein, and other objects not mentioned will be clearly understood by those skilled in the art based on the following descriptions.

Embodiments of the present disclosure may provide a semiconductor device and a method of manufacturing the same, in which interference between wirings can be minimized.

Embodiments of the present disclosure may provide a semiconductor device comprising a first semiconductor structure including a peripheral circuit and a periphery bonding pad connected to the peripheral circuit, and a second semiconductor structure including a cell bonding pad bonded to the periphery bonding pad, a plurality of first wirings connected to the cell bonding pad, a plurality of spacers respectively disposed on side surfaces of the plurality of first wirings, and a first insulating layer covering side surfaces of the plurality of spacers and lower surfaces of the plurality of first wirings, and having air gaps disposed between the plurality of spacers.

Embodiments of the present disclosure may provide a semiconductor device comprising a first semiconductor structure including a peripheral circuit, and a second semiconductor structure bonded to the first semiconductor structure. The second semiconductor structure may include a plurality of first wirings, each comprising a first wiring portion and a second wiring portion continuous with the first wiring portion, the second wiring portion having a variable width, a maximum width of the second wiring portion greater than a width of the first wiring portion, and a first insulating layer having air gaps disposed between the plurality of first wirings.

Embodiments of the present disclosure may provide a method of manufacturing a semiconductor device comprising: forming a plurality of first trenches in a second insulating layer on a substrate; forming a plurality of spacers on side surfaces of the plurality of first trenches, respectively; forming a plurality of first wirings in the plurality of first trenches, respectively; removing the insulating layer; and forming a first insulating layer having air gaps formed between the plurality of spacers.

According to embodiments of the present disclosure, a semiconductor device and a method of manufacturing the semiconductor device capable of minimizing interference between wirings may be provided.

The effects of the embodiments of the present disclosure are not limited to those described above, and additional effects not mentioned will be clearly understood by those skilled in the art based on the appended claims.

### BRIEF DESCRIPTION OF THE DRAWINGS

The present disclosure will be more fully understood from the following detailed description and the accompanying drawings, which are provided solely for illustrative purposes and are not intended to limit the scope of the present disclosure.

FIG. 1 is a cross-sectional view illustrating an example of a semiconductor device according to an embodiment of the present disclosure.

FIG. 2 is an enlarged view of region 197 in FIG. 1.

FIG. 3 is an enlarged view of region 199 in FIG. 1.

FIG. 4 is another cross-sectional view illustrating a semiconductor device according to an embodiment of the present disclosure.

FIGS. 5-19 are cross-sectional views illustrating examples of a method of manufacturing a semiconductor device according to an embodiment of the present disclosure.

FIGS. 20-25 are cross-sectional views illustrating another example of a method of manufacturing a semiconductor device according to an embodiment of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element "is connected or coupled to", “contacts or overlaps” etc., a second element, it should be interpreted that, not only can the first element “be directly connected or coupled to” or “directly contact or overlap” the second element, but a third element can also be "interposed" between the first and second elements, or the first and second elements can "be connected or coupled to", “contact or overlap”, etc., each other via a fourth element. Here, the second element may be included in at least one of two or more elements that "are connected or coupled to", “contact or overlap”, etc., each other.

When time relative terms, such as "after," "subsequent to," "next," "before," and the like, are used to describe processes or operations of elements or configurations, or flows or steps in operating, processing, manufacturing methods, these terms may be used to describe non-consecutive or non-sequential processes or operations unless the term "directly" or "immediately" is used together.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the present disclosure will be described in detail with reference to accompanying drawings.

In the accompanying drawings, two directions parallel to the upper surface of the substrate are defined as first direction FD and second direction SD, respectively, and a direction protruding perpendicularly from the upper surface of the substrate is defined as third direction VD. The first direction FD and the second direction SD may be substantially perpendicular to each other. The third direction VD is perpendicular to both the first direction FD and the second direction SD. In the following description, the terms "vertical" or "vertical direction" are used to indicate a direction substantially the same as the third direction VD. The direction indicated by an arrow in the drawings and the opposite direction both represent the same direction.

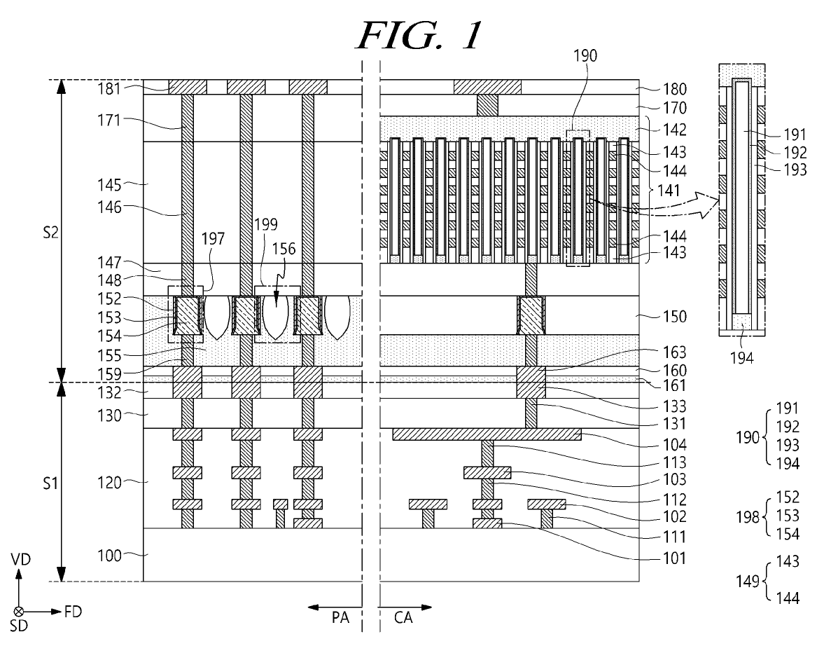

FIG. 1 is a cross-sectional view illustrating an example of a semiconductor device according to an embodiment of the present disclosure.

Referring to FIG. 1, the semiconductor device may include a cell area CA and a periphery area PA. A memory cell array 141 may be disposed in the cell area CA. The periphery area PA may be disposed around the cell area CA. The periphery area PA may include circuits and wirings for transmitting signals to the memory cell array 141, or various circuits and wirings for connecting the semiconductor device to external devices.

The semiconductor device may include a first semiconductor structure S1 and a second semiconductor structure S2. The first semiconductor structure S1 and the second semiconductor structure S2 may be bonded to each other. Specifically, a lower surface of the second semiconductor structure S2 may be bonded to an upper surface of the first semiconductor structure S1. An interface between the first semiconductor structure S1 and the second semiconductor structure S2 may be referred to as a bonding interface.

The first semiconductor structure S1 of the semiconductor device may include a second substrate 100, a gate 101, wirings 102, 103, and 104, contacts 111, 112, and 113, a periphery bonding pad 133, a periphery bonding contact 131, a periphery bonding insulating layer 132, a third insulating layer 120, and a fourth insulating layer 130. In one embodiment, the wirings 102, 103, and 104 and the contacts 111, 112, and 113 included in the first semiconductor structure S1 may be referred to as a peripheral circuit.

The second substrate 100 may include a semiconductor substrate such as a silicon wafer or a silicon-on-insulator (SOI) wafer. The second substrate 100 may include a Group III-V compound semiconductor substrate, for example, a gallium arsenide (GaAs) substrate. The second substrate 100 may include single-crystal silicon, polysilicon, amorphous silicon, monocrystalline silicon germanium, polycrystalline silicon germanium, carbon-doped silicon, or a combination thereof.

The gate 101, first, second and third contacts 111, 112, and 113, first, second and third wirings 102, 103, and 104, and the third insulating layer 120 may be disposed on the second substrate 100. The contacts 111, 112, and 113 may be disposed between the wirings 102, 103, and 104, or between the second wiring 102 and the second substrate 100. The contacts 111, 112, and 113 may be electrically connected to the wirings 102, 103, and 104. The gate 101, the first contact 111, and the second wiring 102 may constitute a transistor.

The gate 101, the contacts 111, 112, and 113, and the wirings 102, 103, and 104 may include a conductive material such as a metal, metal oxide, metal nitride, metal silicide, polysilicon, conductive carbon, or a combination thereof. The third insulating layer 120 may include silicon oxide, silicon nitride, silicon oxynitride, a high-k dielectric, or a combination thereof.

The fourth insulating layer 130 may be disposed on the third insulating layer 120 and the third wiring 104. The periphery bonding contact 131 may be disposed in the fourth insulating layer 130. The periphery bonding contact 131 may be connected to a corresponding third wiring 104.

The periphery bonding insulating layer 132 may be disposed on the fourth insulating layer 130 and the periphery bonding contact 131. The periphery bonding pad 133 may be disposed in the periphery bonding insulating layer 132. The periphery bonding pad 133 may be connected to the corresponding periphery bonding contact 131. An upper surface of the periphery bonding pad 133 may be substantially coplanar with an upper surface of the periphery bonding insulating layer 132.

The second semiconductor structure S2 may be disposed on the first semiconductor structure S1. The second semiconductor structure S2 may include wirings 154 and 181, a spacer 152, a barrier layer 153, contacts 146, 148, and 171, a first insulating layer 155, a second insulating layer 150, a fifth insulating layer 147, a sixth insulating layer 145, a seventh insulating layer 170, an eighth insulating layer 180, a memory cell array 141, a first cell bonding insulating layer 160, a second cell bonding insulating layer 161, a cell bonding contact 159, and a cell bonding pad 163.

In the cell area CA and the periphery area PA, the second cell bonding insulating layer 161 may be disposed on the periphery bonding insulating layer 132. The first cell bonding insulating layer 160 may be disposed on the second cell bonding insulating layer 161. The cell bonding pad 163 may be disposed in the first and second cell bonding insulating layers 160 and 161. A lower surface of the cell bonding pad 163 may be substantially coplanar with a lower surface of the second cell bonding insulating layer 161. The lower surface of the cell bonding pad 163 may be in contact with an upper surface of the corresponding periphery bonding pad 133. In one embodiment, the cell bonding pad 163 may be bonded to the periphery bonding pad 133. The lower surface of the second cell bonding insulating layer 161 may be in contact with an upper surface of the periphery bonding insulating layer 132. In one embodiment, the second cell bonding insulating layer 161 may be bonded to the periphery bonding insulating layer 132.

In the cell area CA and the periphery area PA, the first insulating layer 155 and the cell bonding contact 159 may be disposed on the first cell bonding insulating layer 160 and the cell bonding pad 163. The cell bonding contact 159 may be connected to the corresponding cell bonding pad 163.

The periphery bonding contact 131, the cell bonding contact 159, the periphery bonding pad 133, and the cell bonding pad 163 may include a conductive material such as a metal, metal oxide, metal nitride, metal silicide, polysilicon, conductive carbon, or a combination thereof. In one embodiment, the periphery bonding contact 131 and the cell bonding contact 159 may include titanium nitride (TiN), tungsten (W), or a combination thereof. In one embodiment, the periphery bonding pad 133 and the cell bonding pad 163 may include tantalum nitride (TaN), copper, or a combination thereof. The periphery bonding insulating layer 132, the first cell bonding insulating layer 160, the second cell bonding insulating layer 161, the first insulating layer 155, and the fourth insulating layer 130 may include silicon oxide, silicon nitride, silicon oxynitride, a high-k dielectric, or a combination thereof.

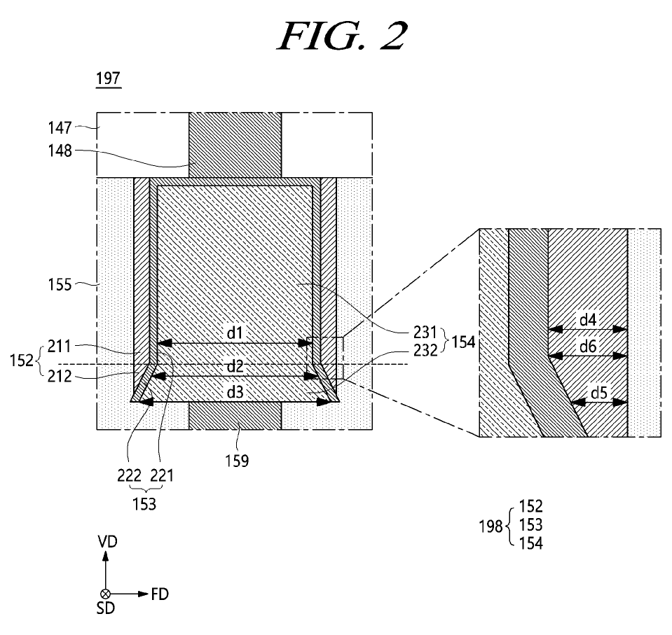

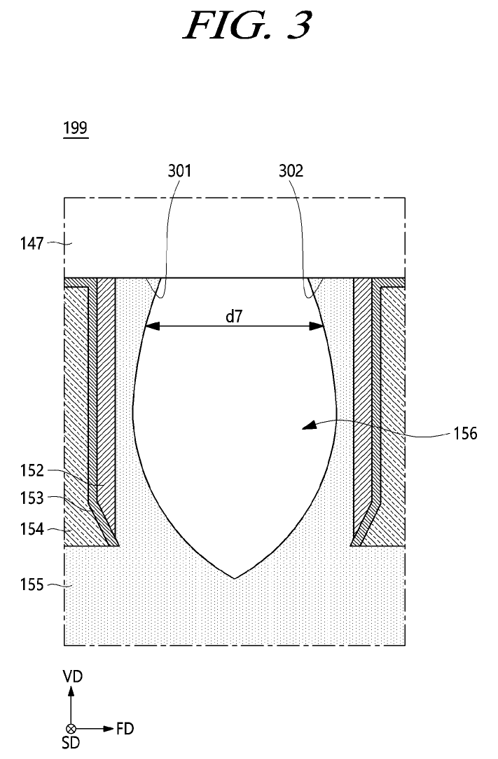

In the periphery area PA, the cell bonding contact 159, a wiring structure 198, and an air gap 156 may be disposed in the first insulating layer 155. The wiring structure 198 may include the spacer 152, the barrier layer 153 and the wiring 154, and be disposed on the cell bonding contact 159. The air gap 156 may be disposed between a plurality of wiring structures 198. An upper surface of the cell bonding contact 159 may be in contact with a lower surface of the wiring structure 198. The wiring structure 198 is described herein below with reference to FIG. 2. The air gap 156 is described herein below with reference to FIG. 3.

In the periphery area PA, the fifth insulating layer 147 and a fifth contact 148 may be disposed on the first insulating layer 155 and the wiring structure 198. The fifth contact 148 may be connected to the wiring structure 198. A fourth contact 146 and a sixth contact 171 may be sequentially stacked on the fifth contact 148. The fourth contact 146 may be connected to the fifth contact 148. The sixth contact 171 may be connected to the fifth contact 148. A fifth wiring 181 may be connected to the corresponding sixth contact 171. The fourth contact 146, the fifth contact 148, the sixth contact 171, and the fifth wiring 181 may include a conductive material such as a metal, metal oxide, metal nitride, metal silicide, polysilicon, conductive carbon, or a combination thereof. The fifth contact 148 may be disposed in the fifth insulating layer 147. The fourth contact 146 may be disposed in the sixth insulating layer 145. The sixth contact 171 may be disposed in the seventh insulating layer 170. The fifth wiring 181 may be disposed in the eighth insulating layer 180. The first insulating layer 155, the fifth insulating layer 147, the sixth insulating layer 145, the seventh insulating layer 170, and the eighth insulating layer 180 may include silicon oxide, silicon nitride, silicon oxynitride, a low-k dielectric, a high-k dielectric, or a combination thereof.

In the cell area CA, the cell bonding contact 159 may be disposed in the first insulating layer 155. The second insulating layer 150 and the wiring structure 198 may be disposed on the first insulating layer 155. The wiring structure 198 may be disposed in the second insulating layer 150. The second insulating layer 150 may include silicon oxide, silicon nitride, silicon oxynitride, a low-k dielectric, a high-k dielectric, or a combination thereof. In one embodiment, the second insulating layer 150 may include silicon oxide.

In the cell area CA, the fifth insulating layer 147 and the fifth contact 148 may be disposed on the second insulating layer 150 and the wiring structure 198. The fifth contact 148 may be disposed in the fifth insulating layer 147. The fifth contact 148 may be connected to the wiring structure 198. The memory cell array 141 may be disposed on the fifth insulating layer 147 and the fifth contact 148.

The memory cell array 141 may include a stacked structure 149, a channel structure 190, and a source plate 142. In one embodiment, the stacked structure 149 may include interlayer insulating layers 143 (for example, dielectric layers) and electrode layers 144 alternately stacked in a vertical direction.

The channel structure 190 may vertically penetrate the interlayer insulating layers 143 and the electrode layers 144. The channel structure 190 may extend into the source plate 142 in the vertical direction. An upper surface of the channel structure 190 may be positioned higher than a lower surface of the source plate 142 in the vertical direction. A lower surface of the channel structure 190 may be substantially coplanar with a lower surface of the lowest interlayer insulating layer 143 disposed at the lowest part of the memory cell array 141.

The channel structure 190 may be connected to a corresponding fifth contact 148. The channel structure 190 may be connected to the first semiconductor structure S1 via the corresponding fifth contact 148, the wiring structure 198 corresponding to the fifth contact 148, the cell bonding pad 163 corresponding to the wiring structure 198, the periphery bonding pad 133 connected to the cell bonding pad 163, and the periphery bonding contact 131 corresponding to the periphery bonding pad 133.

The channel structure 190 may include a core layer 191, a channel pattern 192, a gate insulating layer 193, and a drain pad 194. The drain pad 194 may be in contact with an upper surface of the fifth contact 148. The core layer 191 may be disposed on the drain pad 194. The core layer 191 may extend vertically. The channel pattern 192 may surround side and bottom surfaces of the core layer 191. The channel pattern 192 may extend into the source plate 142 in the vertical direction. The gate insulating layer 193 may surround the side surface of the channel pattern 192 and the drain pad 194. An electrode layer 144, the gate insulating layer 193, and a portion of the channel pattern 192 overlapping with the electrode layer 144 in the first direction or the second direction may constitute a memory cell.

The source plate 142 may be disposed on the uppermost interlayer insulating layer 143 of the memory cell array 141 and on the channel structure 190.

The seventh insulating layer 170 and the sixth contact 171 may be disposed on the source plate 142. The sixth contact 171 may vertically penetrate the seventh insulating layer 170 to connect to the source plate 142. The eighth insulating layer 180 and the fifth wiring 181 may be disposed on the seventh insulating layer 170 and the sixth contact 171. The fifth wiring 181 may vertically penetrate the eighth insulating layer 180 to connect to the sixth contact 171.

The fifth contact 148, the electrode layer 144, the drain pad 194, the sixth contact 171, and the fifth wiring 181 may include a conductive material such as a metal, metal oxide, metal nitride, metal silicide, polysilicon, conductive carbon, or a combination thereof. The channel pattern 192 and the source plate 142 may include a semiconductor material such as polysilicon.

FIG. 2 is an enlarged view of 197 in FIG. 1.

Referring to FIG. 2, the wiring structure 198 may include a first wiring 154, the barrier layer 153, and the spacer 152. The barrier layer 153 may surround the side and upper surfaces of the first wiring 154. The spacer 152 may be disposed on the side surface of the barrier layer 153. In one embodiment, the spacer 152 may be disposed on the side surface of the first wiring 154.

In the illustrated example of FIG. 2, the first wiring 154 may include a first wiring portion 231 and a second wiring portion 232. The first wiring portion 231 may be located on the second wiring portion 232. The second wiring portion 232 may be continuous with the first wiring portion 231. The cross-sectional side surfaces of the first wiring portion 231 may be parallel to each other. The width d1 of the first wiring portion 231 in the first direction may be constant. The side surfaces of the second wiring portion 232 in cross-section may not be parallel to each other and may be curved outward toward the bottom. The width d2 of the second wiring portion 232 in the first direction may increase toward the bottom. The maximum width d3 of the second wiring portion 232 in the first direction may be greater than the width of the first wiring portion 231 in the first direction. The first wiring 154 may include a conductive material such as a metal, metal oxide, metal nitride, metal silicide, polysilicon, conductive carbon, or a combination thereof. In one embodiment, the first wiring 154 may include copper (Cu), copper-manganese alloy (CuMn), aluminum (Al), tungsten (W), or a combination thereof.

The barrier layer 153 includes a first barrier portion 221 and a second barrier portion 222. The first barrier portion 221 may be disposed on the side and upper surfaces of the first wiring portion 231. The second barrier portion 222 may be disposed on the side and upper surfaces of the second wiring portion 232. The second barrier portion 222 may protrude outward in the first direction or the second direction toward the bottom. The barrier layer 153 may include a conductive material such as a metal, metal oxide, metal nitride, metal silicide, polysilicon, conductive carbon, or a combination thereof. In one embodiment, the barrier layer 153 may include tantalum nitride (TaN), tungsten nitride (WN), titanium nitride (TiN), or a combination thereof.

In the illustrated example of FIG. 2, the spacer 152 may be disposed on the side surface of the first wiring 154 or the barrier layer 153. The spacer 152 includes a first spacer portion 211 and a second spacer portion 212. The first spacer portion 211 may be disposed on the side surface of the first barrier portion 221. The second spacer portion 212 may be disposed on the side surface of the second barrier portion 222. The side surfaces of the first spacer portion 211 may be parallel to each other (for example, having the same width of cross-section along the entire length of the first spacer portion 211). The width d4 of the first spacer portion 211 in the first direction may be constant. The cross-section of the second spacer portion 212 may be curved outward toward the bottom and not parallel. The width d5 of the second spacer portion 212 in the first direction may decrease toward the bottom. The maximum width d6 of the second spacer portion 212 in the first direction may be smaller than the width d4 of the first spacer portion 211 in the first direction. The spacer 152 may include silicon oxide, silicon nitride, silicon oxynitride, a low-k dielectric, a high-k dielectric, or a combination thereof.

When the spacer 152 is disposed on the side surface of the first wiring 154 or the barrier layer 153, it can prevent leakage current. Specifically, if the first insulating layer 155 is not deposited on the side surface of the first wiring 154 or the barrier layer 153, leakage current may occur from the first wiring 154. To prevent this, the spacer 152 may be disposed on the side surface of the first wiring 154 or the barrier layer 153. In one embodiment, the breakdown voltage drop due to leakage current between first wirings 154 can be controlled by placing the spacer 152.

An inner surface of the first barrier portion 221 may contact the first wiring portion 231. An outer surface of the first barrier portion 221 may contact the first spacer portion 211, the fifth insulating layer 147, and the fifth contact 148. An inner surface of the second barrier portion 222 may contact the first wiring portion 231 and the first insulating layer 155. An outer surface of the second barrier portion 222 may contact the second spacer portion 212 and the first insulating layer 155.

FIG. 3 is an enlarged view of 199 in FIG. 1.

Referring to FIG. 3, the air gap 156 may be disposed in the first insulating layer 155 and may be located between adjacent wiring structures 198. The insulating material of the first insulating layer 155 may be positioned between the spacer 152 of the wiring structure 198 and the air gap 156. In one embodiment, the entire side surface of the air gap 156 may be in contact with the insulating material of the first insulating layer 155. In another embodiment, part of the side surface of the air gap 156 may contact the side surface of the spacer 152.

The width d7 of the air gap 156 in the first direction may vary in the vertical direction. Specifically, the width d7 of the air gap 156 in the first direction may be maintained, increased, or decreased in the vertical direction. In one embodiment, the width d7 of the air gap 156 in the first direction may repeatedly maintain, increase, and decrease along the vertical direction.

The first surface 301 and the second surface 302 may be located between a plurality of adjacent wiring structures 198. The first surface 301 may be on the side surface of one of the adjacent wiring structures 198. The second surface 302 may be on the side surface of the other of the adjacent wiring structures 198. The first surface 301 and the second surface 302 may be surfaces coplanar with the lower surface of the fifth insulating layer 147. In one embodiment, the air gap 156 may contact the lower surface of the fifth insulating layer 147 in portions other than the areas corresponding to the first surface 301 and the second surface 302. In another embodiment, the air gap 156 may not contact the lower surface of the fifth insulating layer 147 including the first surface 301 and the second surface 302.

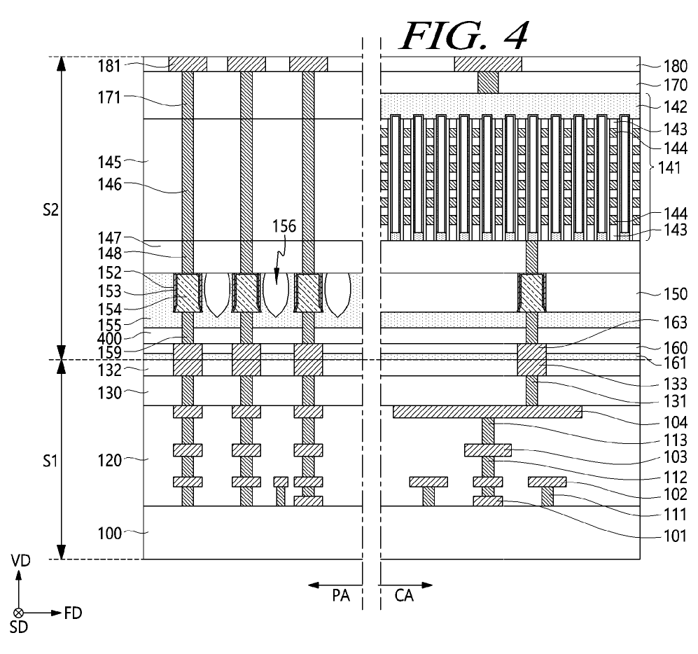

FIG. 4 illustrates another example of a cross-sectional structure of a semiconductor device according to an embodiment of the present disclosure.

Referring to FIG. 4, a ninth insulating layer 400 may be disposed on the first cell bonding insulating layer 160 and the cell bonding pad 163, in addition to the structure of FIG. 1. The first insulating layer 155 may be disposed on the ninth insulating layer 400. The cell bonding contact 159 may be disposed within the first insulating layer 155 and the ninth insulating layer 400. The cell bonding contact 159 may penetrate through the first insulating layer 155 and the ninth insulating layer 400. A lower surface of the cell bonding contact 159 may be substantially coplanar with a lower surface of the ninth insulating layer 400.

The ninth insulating layer 400 may include silicon oxide, silicon nitride, silicon oxynitride, a low-k dielectric, a high-k dielectric, or a combination thereof. In one embodiment, the ninth insulating layer 400 may include an oxide.

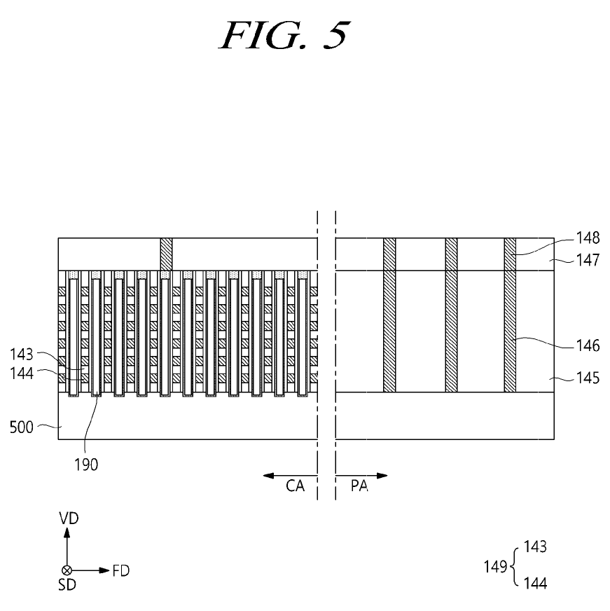

FIGS. 5-19 illustrate examples of a method of manufacturing a semiconductor device according to an embodiment of the present disclosure.

Referring to FIG. 5, a first substrate 500 is prepared. The first substrate 500 may include a semiconductor substrate such as a silicon wafer or a silicon-on-insulator (SOI) wafer. The first substrate 500 may include a Group III-V compound semiconductor substrate, such as gallium arsenide (GaAs). The first substrate 500 may include single-crystal silicon, polysilicon, amorphous silicon, monocrystalline silicon-germanium, polycrystalline silicon-germanium, carbon-doped silicon, or a combination thereof.

In a cell region CA, interlayer insulating layers (e.g., interlayer dielectric layers) 143 and electrode layers 144 may be alternately stacked on the first substrate 500 to form a stacked structure 149. The channel structure 190 may be formed to vertically penetrate the interlayer insulating layers 143 and the electrode layers 144. In the periphery region PA, a sixth insulating layer 145 may be formed on the first substrate 500. After the sixth insulating layer 145 is formed, a fourth contact 146 that penetrates the sixth insulating layer 145 may be formed. The process of forming the fourth contact 146 may include forming an etching structure in the sixth insulating layer 145, depositing a conductive material, and performing a planarization process. The planarization process may include a grinding process or a chemical mechanical polishing (CMP) process. An upper surface of the sixth insulating layer 145 may be substantially coplanar with an upper surface of the fourth contact 146.

The fifth insulating layer 147 may be formed on the sixth insulating layer 145, the channel structure 190, and the interlayer insulating layer 143. In the cell region CA, the fifth contact 148 may be formed to penetrate the fifth insulating layer 147. The fifth contact 148 may be connected to a corresponding channel structure 190. In the periphery region PA, the fifth contact 148 may also be formed to penetrate the fifth insulating layer 147. The process of forming the fifth contact 148 may include forming an etching structure in the fifth insulating layer 147, depositing a conductive material, and performing a planarization process. The planarization process may include a grinding process or a chemical mechanical polishing (CMP) process. An upper surface of the fifth insulating layer 147 may be substantially coplanar with an upper surface of the fifth contact 148.

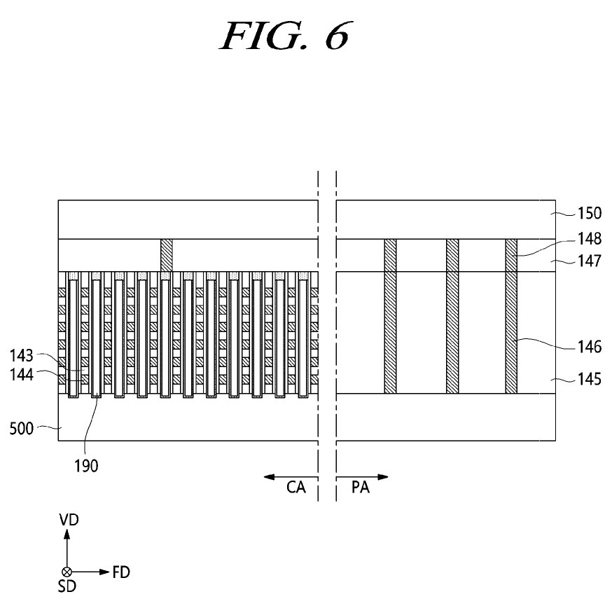

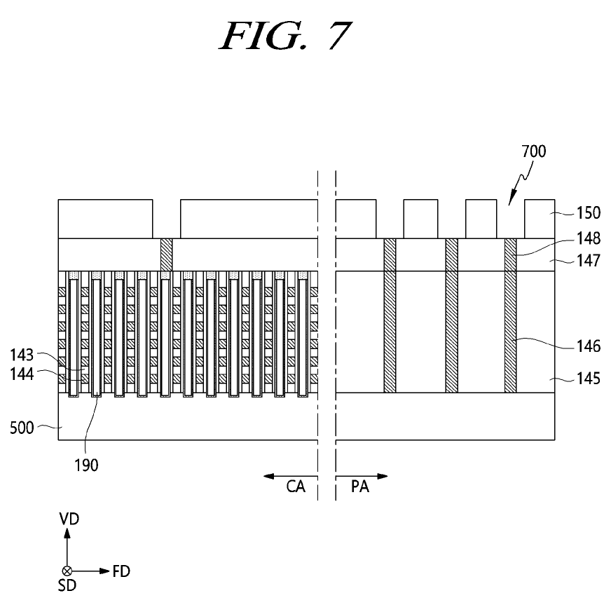

Referring to FIG. 6 and FIG. 7, a second insulating layer 150 may be formed on the fifth insulating layer 147 in the cell region CA and the periphery region PA. A plurality of first trenches 700 may be formed in regions where an upper surface of the fifth contact 148 is in contact with the second insulating layer 150. The process of forming the first trenches 700 may include a photolithography process or an etching process. For example, the process of forming the first trenches 700 may include coating an insulating material over the cell region CA and the periphery region PA and then removing a portion of the insulating material to form the trenches 700.

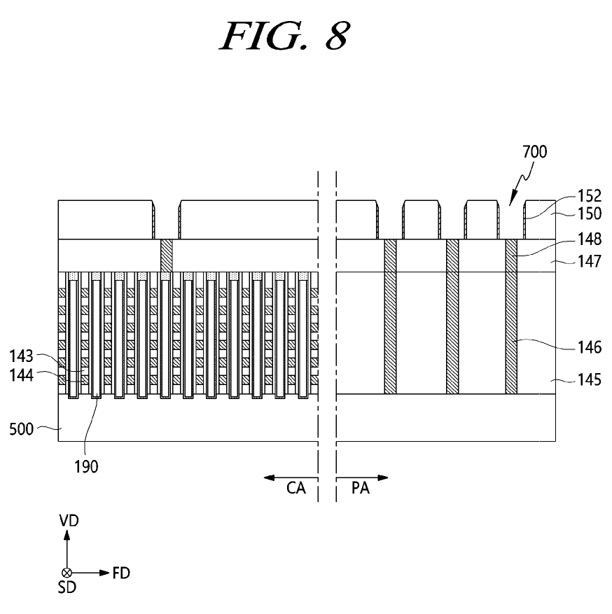

Referring to FIG. 8, spacers 152 may be respectively formed on sidewalls of each of the plurality of first trenches 700 in the cell region CA and the periphery region PA. The process of forming the spacers 152 may include an etching process. For example, the process may include depositing an insulating material over the cell region CA and the periphery region PA of the second insulating layer 150, removing the insulating material located in the vertical direction VD over the second insulating layer 150 including the first trenches 700, and leaving the insulating material on the sidewalls of the first trenches 700. As a result of the etching process, a width of an upper portion of each spacer 152 may decrease in the vertical direction. The insulating material may include silicon oxide, silicon nitride, silicon oxynitride, a low-k dielectric, a high-k dielectric, or a combination thereof. In one embodiment, the ninth insulating layer 400 may include an oxide.

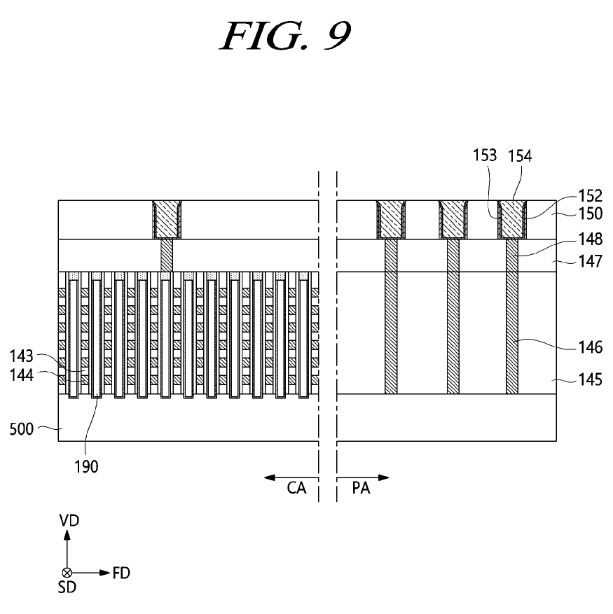

Referring to FIG. 9, in the cell region CA and the periphery region PA, the barrier layer 153 and the first wiring 154 may be respectively formed in the plurality of first trenches 700 of the second insulating layer 150. The barrier layer 153 and the first wiring 154 are positioned between the spacers 152. An upper portion of the barrier layer 153 may protrude in a first direction FD or a second direction SD. A width of an upper portion of the first wiring 154 may increase in the vertical direction VD. The process of forming the barrier layer 153 and the first wiring 154 may include depositing a conductive material for each layer and performing a planarization process. The planarization process may include a grinding process or a chemical mechanical polishing (CMP) process. The conductive material may include a metal, metal oxide, metal nitride, metal silicide, polysilicon, conductive carbon, or a combination thereof. In one embodiment, the conductive material for the barrier layer 153 may include tantalum nitride (TaN), tungsten nitride (WN), or a combination thereof. In another embodiment, the conductive material for the first wiring 154 may include copper.

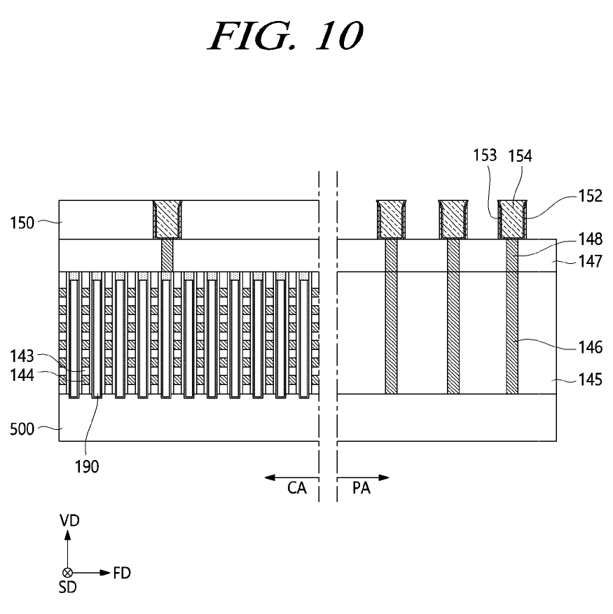

Referring to FIG. 10, in the periphery region PA, the second insulating layer 150 may be removed. The process of removing the second insulating layer 150 may include a photolithography process or an etching process. When the spacer 152 is disposed on a side surface of the first wiring 154 or the barrier layer 153, the spacer 152 may prevent the first wiring 154 or the barrier layer 153 from being lifted together with the second insulating layer 150 during the removal process of the second insulating layer 150.

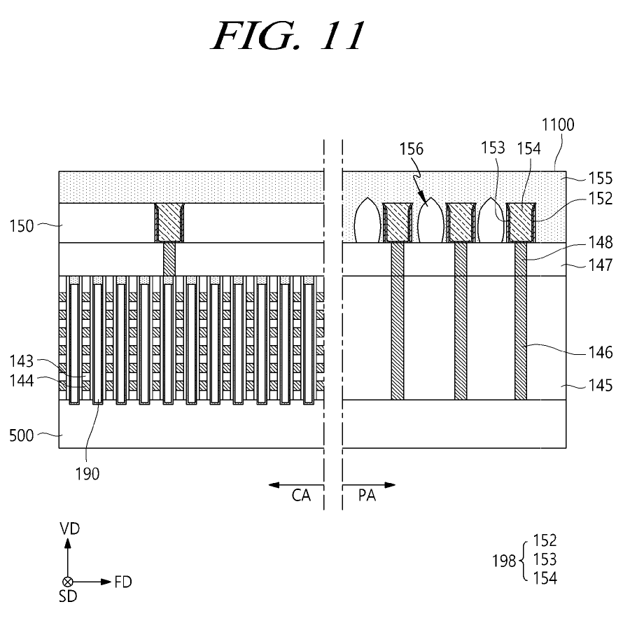

Referring to FIG. 11, in the cell region CA, the first insulating layer 155 may be formed on the second insulating layer 150 and the wiring structure 198 (which includes, for example, the first wiring 154, the barrier layer 153, and the spacer 152). In the periphery region PA, the first insulating layer 155 may be formed on the fifth insulating layer 147 and the fifth contact 148. The process of forming the first insulating layer 155 may include depositing an insulating material and performing a planarization process. The planarization process may include a chemical mechanical polishing (CMP) process. An upper surface of the first insulating layer 155 may be flat. In one embodiment, a thickness from an interface between the first insulating layer 155 and the fifth insulating layer 147 to an upper surface of the first insulating layer 155 may range from 500 to 2000 angstroms (Å).

The insulating material of the first insulating layer 155 may have an overhang property. The insulating material may be deposited on upper and side surfaces of the wiring structure 198 and may form an overhang shape between adjacent wiring structures 198. For example, the width of the insulating material deposited on the upper surface of the wiring structure 198 may be greater than that deposited on its side surface. Accordingly, the insulating material deposited on the upper surface of one of the adjacent wiring structures 198 may contact the insulating material on the upper surface of another adjacent wiring structure 198, while the insulating material deposited on a side surface of one of the plurality of adjacent wiring structures 198 may be spaced apart from the insulating material deposited on a side surface of another adjacent wiring structure 198. As a result, the air gap 156 may be formed between the adjacent wiring structures 198. The insulating material may include silicon oxide, silicon nitride, silicon oxynitride, a low-k dielectric, a high-k dielectric, or a combination thereof.

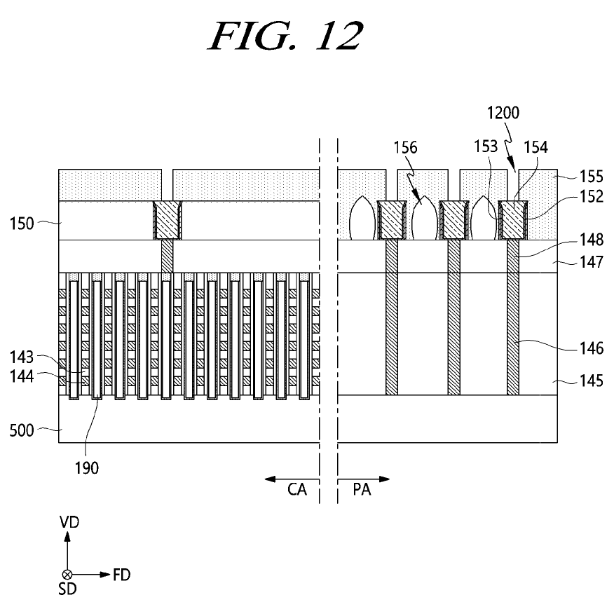

Referring to FIG. 12, in the cell region CA and the periphery region PA, a plurality of second trenches 1200 may be formed on the wiring structure 198 in the first insulating layer 155. The process of forming the second trenches 1200 may include a photolithography process or an etching process. Through this process, an upper surface of the first wiring 154 may be exposed.

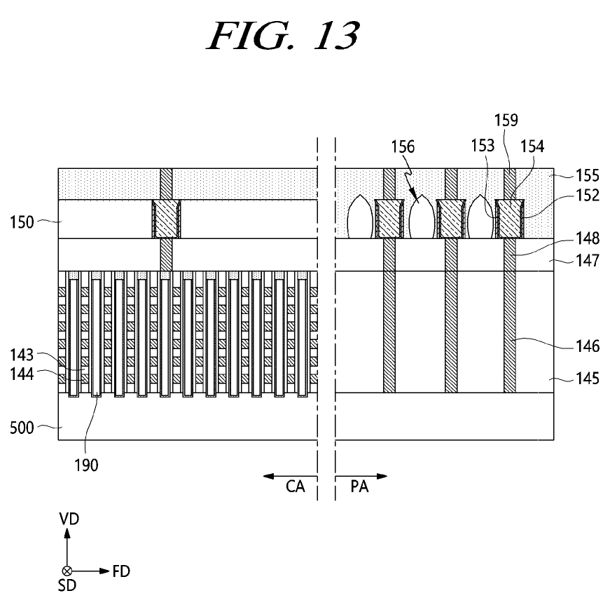

Referring to FIG. 13, in the cell region CA and the periphery region PA, the cell bonding contact 159 that can be connected to the first wiring 154 may be formed in the first insulating layer 155. The process of forming the cell bonding contact 159 may include depositing a conductive material and performing a planarization process. The planarization process may include a grinding process or a chemical mechanical polishing (CMP) process. An upper surface of the cell bonding contact 159 may be substantially coplanar with an upper surface of the first insulating layer 155. The conductive material may include a metal, metal oxide, metal nitride, metal silicide, polysilicon, conductive carbon, or a combination thereof. In one embodiment, the cell bonding contact 159 may include titanium nitride (TiN), tungsten (W), or a combination thereof.

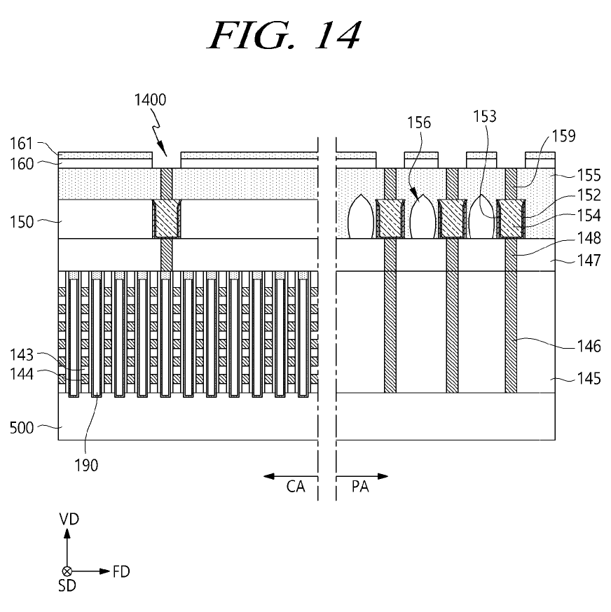

Referring to FIG. 14, in the cell region CA and the periphery region PA, the first cell bonding insulating layer 160 may be formed on the first insulating layer 155 and the cell bonding contact 159. A second cell bonding insulating layer 161 may be formed on the first cell bonding insulating layer 160. A third trench 1400 may be formed on the cell bonding contact 159 in the first and second cell bonding insulating layers 160 and 161. Through the process of forming the third trench 1400, an upper surface of the cell bonding contact 159 may be exposed to the outside. The process of forming the third trench 1400 may include a photolithography process or an etching process.

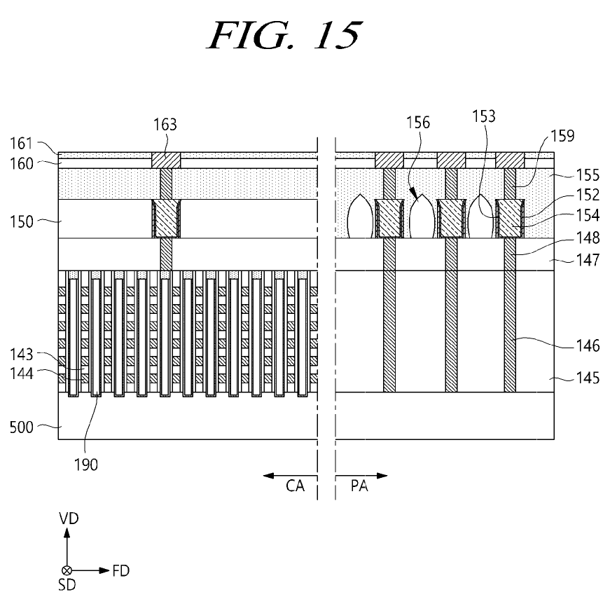

Referring to FIG. 15, in the cell region CA and the periphery region PA, the cell bonding pad 163 may be formed on the cell bonding contact 159. The cell bonding pad 163 may be formed to fill the third trench 1400 formed in the first and second cell bonding insulating layers 160 and 161. The process of forming the cell bonding pad 163 may include depositing a conductive material and performing a planarization process. The planarization process may include a grinding process or a chemical mechanical polishing (CMP) process. An upper surface of the cell bonding pad 163 may be substantially coplanar with an upper surface of the second cell bonding insulating layer 161. The conductive material may include a metal, metal oxide, metal nitride, metal silicide, polysilicon, conductive carbon, or a combination thereof. In one embodiment, the cell bonding pad 163 may include tantalum nitride (TaN), copper (Cu), copper-manganese alloy (CuMn), or a combination thereof.

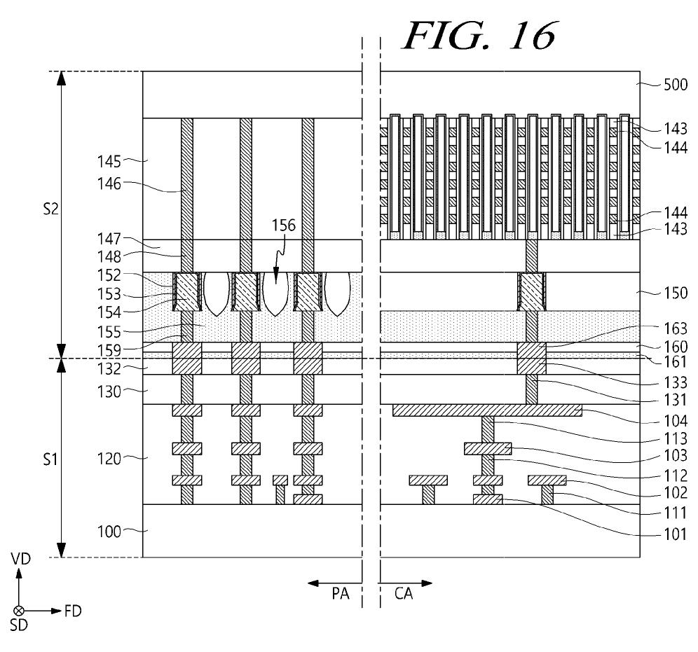

Referring to FIG. 16, a first semiconductor structure S1 is prepared. The cell bonding pad 163 and the second cell bonding insulating layer 161 of a second semiconductor structure S2 may be bonded to the periphery bonding pad 133 and the periphery bonding insulating layer 132 of the first semiconductor structure S1. Note that the structure of FIG. 15 is inverted in FIG. 16, and that the cell bonding pad 163 is bonded to the periphery bonding pad 133. The periphery bonding pad 133 may include tantalum nitride (TaN), copper (Cu), copper-manganese alloy (CuMn), or a combination thereof.

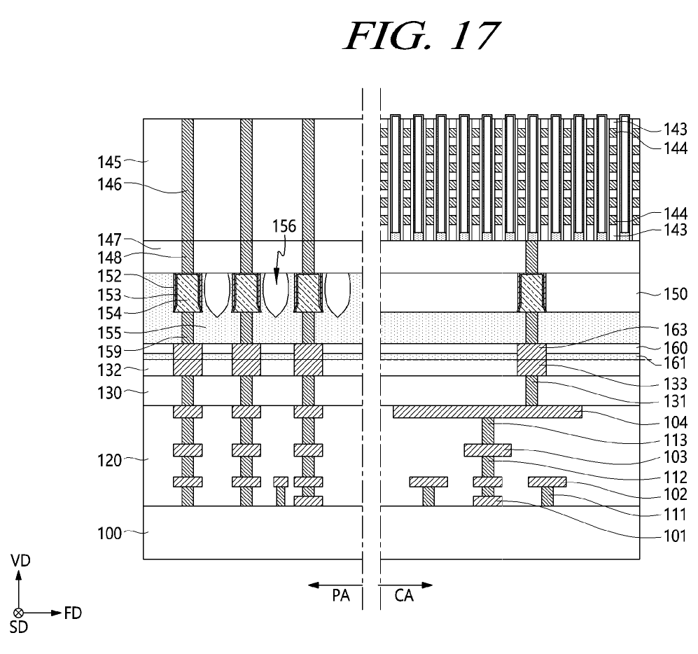

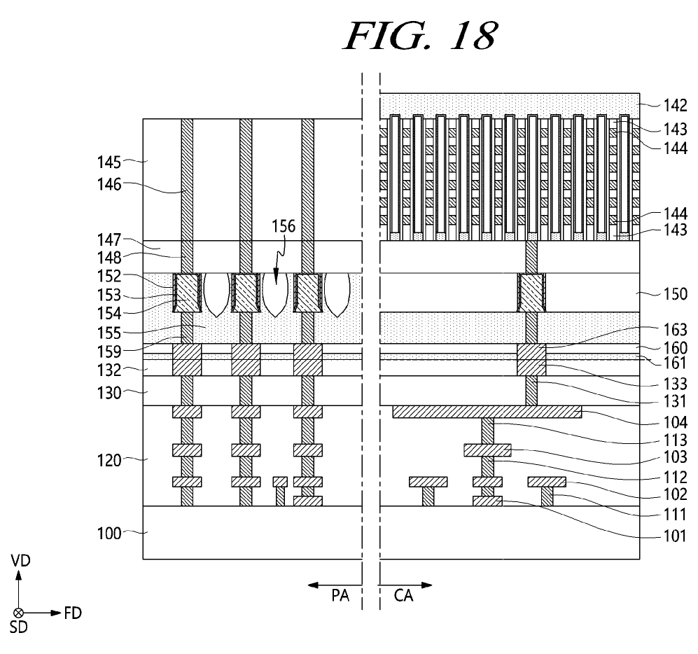

Referring to FIG. 17 and FIG. 18, in the cell region CA and the periphery region PA, the first substrate 500 may be removed. In one embodiment, the process of removing the first substrate 500 may include an etching process, a grinding process, or a chemical mechanical polishing (CMP) process. After the removal of the first substrate 500, a source plate 142 may be formed on the channel structure 190 and the interlayer insulating layer 143 in the cell region CA.

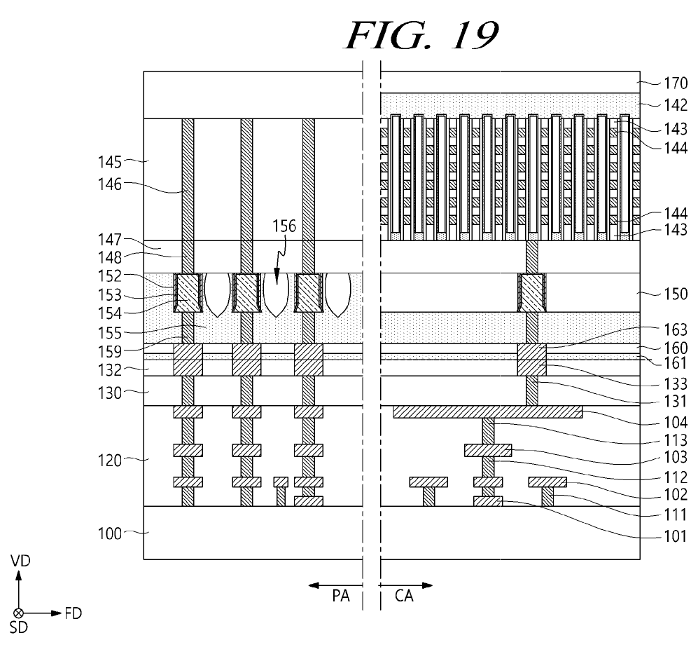

Referring to FIG. 19, a seventh insulating layer 170 may be formed on the source plate 142 in the cell region CA and on the sixth insulating layer 145 and the fourth contact 146 in the periphery region PA. The process of forming the seventh insulating layer 170 may include depositing an insulating material and performing a planarization process. The planarization process may include a grinding process or a chemical mechanical polishing (CMP) process.

Referring back to FIG. 1, in the cell region CA and the periphery region PA, a sixth contact 171 penetrating the seventh insulating layer 170 may be formed. An eighth insulating layer 180 and the fifth wiring 181 may be formed on the sixth contact 171 and the seventh insulating layer 170. The process of forming the sixth contact 171 and the fifth wiring 181 may include a damascene process.

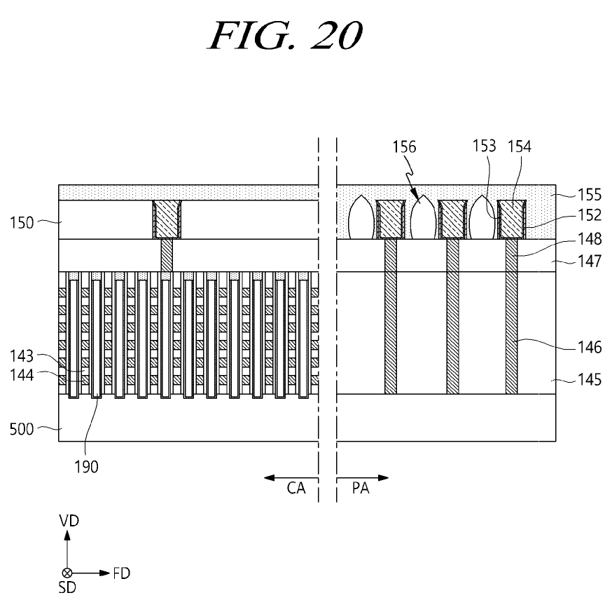

FIGS. 20-25 illustrate other examples of a method of manufacturing a semiconductor device according to embodiments of the present disclosure.

The semiconductor device shown in FIG. 20 may be formed using the same method described with reference to FIG. 5 to FIG. 11.

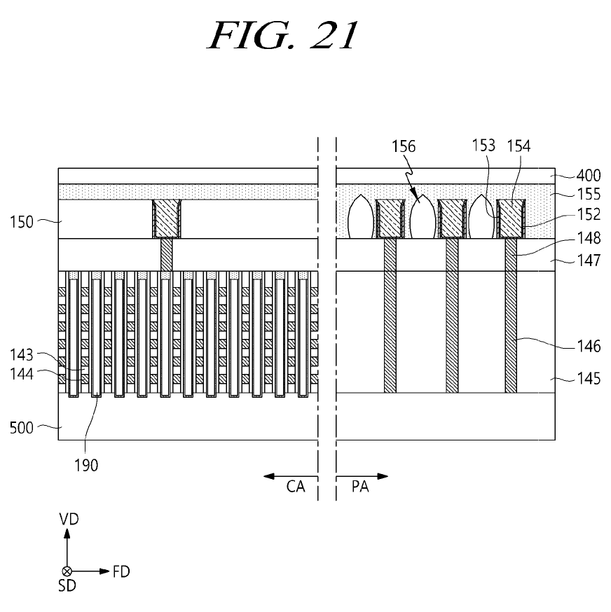

Referring to FIG. 20 and FIG. 21, after planarizing an upper surface of the first insulating layer 155 in the cell region CA and the periphery region PA, the ninth insulating layer 400 may be formed on the first insulating layer 155.

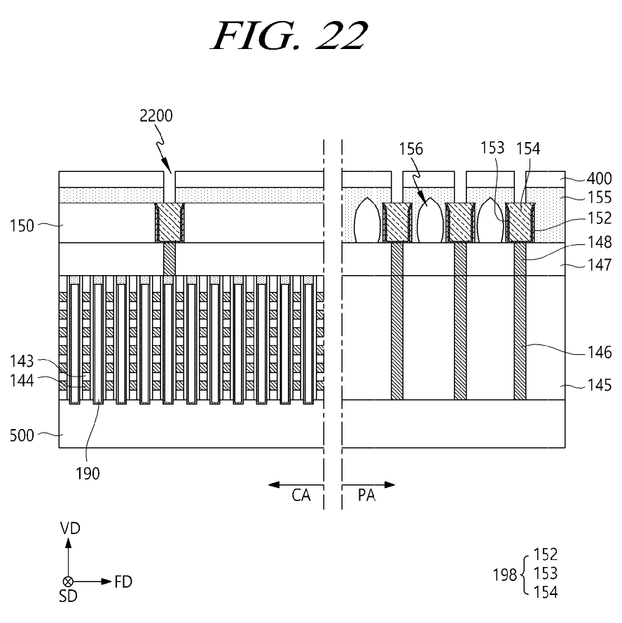

Referring to FIG. 22, a fourth trench 2200 on the wiring structure 198 (which includes, for example, the first wiring 154, the barrier layer 153, and the spacer 152) may be formed in the first insulating layer 155 and the ninth insulating layer 400 in the cell region CA and the periphery region PA. The process of forming the fourth trench 2200 may include a photolithography process or an etching process.

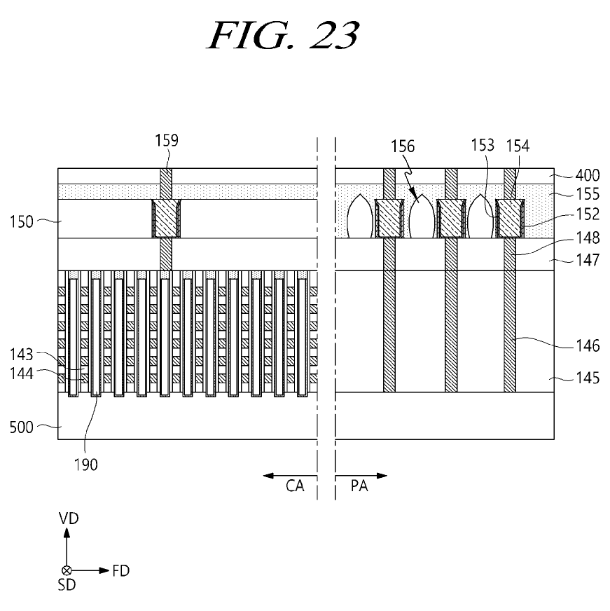

Referring to FIG. 23, the cell bonding contact 159 penetrating the first insulating layer 155 and the ninth insulating layer 400 may be formed in the cell region CA and the periphery region PA. The process of forming the cell bonding contact 159 may include depositing a conductive material to fill the fourth trench 2200, which is located in the first insulating layer 155 and the ninth insulating layer 400, with the conductive material and planarizing the same. The planarization process may include a grinding process or a chemical mechanical polishing (CMP) process. After planarization, an upper surface of the cell bonding contact 159 may be substantially coplanar with an upper surface of the ninth insulating layer 400.

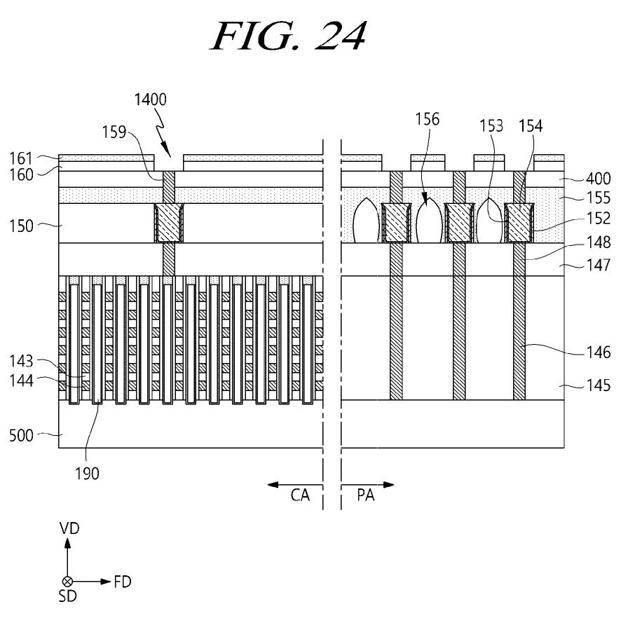

Referring to FIG. 24, the first cell bonding insulating layer 160 may be formed on the ninth insulating layer 400 and the cell bonding contact 159 in the cell region CA and the periphery region PA. The second cell bonding insulating layer 161 may be formed on the first cell bonding insulating layer 160. The third trench 1400 may be formed on the cell bonding contact 159 within the first and second cell bonding insulating layers 160 and 161. The process of forming the third trench 1400 may include a photolithography process or an etching process. As a result, an upper portion of the cell bonding contact 159 may be exposed to the outside.

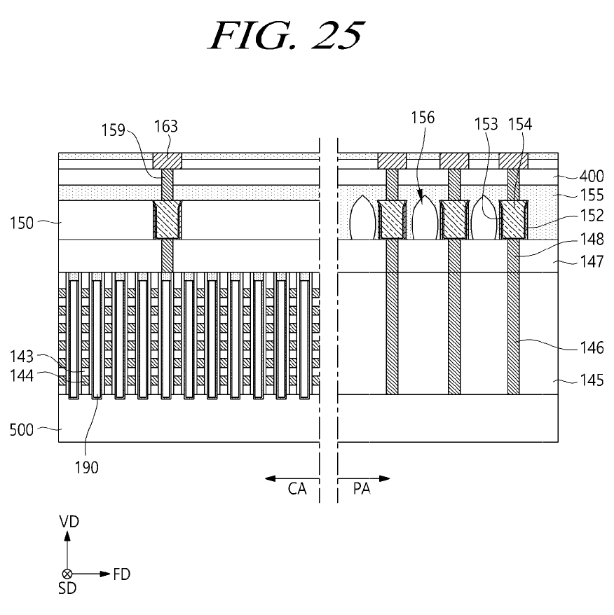

Referring to FIG. 25, the cell bonding pad 163 may be formed in the trench 1400 within the first and second cell bonding insulating layers 160 and 161 in the cell region CA and the periphery region PA. The process of forming the cell bonding pad 163 may include depositing a conductive material and performing a planarization process. The planarization process may include a grinding process or a chemical mechanical polishing (CMP) process. The upper surface of the cell bonding pad 163 may be substantially coplanar with an upper surface of the second cell bonding insulating layer 161.

The processes after FIG. 25 may proceed using the same method as described in FIGS. 16-19 .

According to embodiments of the present disclosure, interference between adjacent wirings resulting from reduced spacing inside the semiconductor device may be minimized. Specifically, by disposing spacers 152 on side surfaces of the first wiring 154 or the barrier layer 153, leakage current between the first wirings 154 may be minimized. Additionally, parasitic capacitance between the wirings may be reduced by forming air gaps 156 between the wiring structures 198. During the process of forming the air gaps 156, the spacers 152 may prevent the first wirings 154 and the barrier layers 153 from being lifted when the second insulating layer 150 is removed.

Although various embodiments of the disclosed technology have been described with particular specifics and varying details for illustrative purposes, those skilled in the art will appreciate that various modifications, additions and substitutions may be made based on what is disclosed or illustrated in the present disclosure without departing from the spirit and scope of the invention as defined in the following claims.

What is claimed is:

1. A semiconductor device comprising:
a first semiconductor structure including
a peripheral circuit, and
a periphery bonding pad connected to the peripheral circuit; and
a second semiconductor structure including
a cell bonding pad bonded to the periphery bonding pad,
a plurality of first wirings connected to the cell bonding pad,
a plurality of spacers respectively disposed on side surfaces of the plurality of first wirings, and
a first insulating layer covering side surfaces of the plurality of spacers and lower surfaces of the plurality of first wirings, and having air gaps disposed between the plurality of spacers.

2. The semiconductor device according to claim 1,
wherein each of the plurality of first wirings comprises a first wiring portion and a second wiring portion continuous with the first wiring portion, and
wherein the second wiring portion has a variable width, and a maximum width of the second wiring portion is greater than a width of the first wiring portion.

3. The semiconductor device according to claim 2, further comprising a barrier layer disposed between the side surfaces of the plurality of first wirings and the plurality of spacers,
wherein the barrier layer comprises:
a first barrier portion disposed on a side surface of the first wiring portion; and
a second barrier portion disposed on a side surface of the second wiring portion, and
wherein the second barrier portion protrudes farther in a first direction than the first barrier portion.

4. The semiconductor device according to claim 3,
wherein the second barrier portion comprises an inner surface and an outer surface, and
wherein the inner surface contacts the first insulating layer.

5. The semiconductor device according to claim 1,
wherein each of the plurality of spacers comprises:
a first spacer portion; and
a second spacer portion continuous with a lower portion of the first spacer portion, and
wherein a maximum width of the second spacer portion is less than a width of the first spacer portion.

6. The semiconductor device according to claim 1,
wherein the plurality of first wirings includes two adjacent first wirings, and
wherein an upper surface of the first insulating layer disposed on a side surface of one of the two adjacent first wirings is separated from an upper surface of the first insulating layer disposed on a side surface of the other one of the two adjacent first wirings.

7. The semiconductor device according to claim 1,
wherein the second semiconductor structure comprises:
a stacked structure in which a plurality of electrodes and insulating layers are alternately stacked; and
a channel structure penetrating the stacked structure, and
wherein at least one of the plurality of first wirings is connected to the channel structure.

8. The semiconductor device according to claim 1,
wherein a lower surface of the first insulating layer is planar.

9. The semiconductor device according to claim 1,
wherein the cell bonding pad is in contact with a lower surface of the first insulating layer.

10. A semiconductor device comprising:
a first semiconductor structure including a peripheral circuit; and
a second semiconductor structure bonded to the first semiconductor structure,
wherein the second semiconductor structure comprises:
a plurality of first wirings each comprising a first wiring portion and a second wiring portion continuous with the first wiring portion, the second wiring portion having a variable width, a maximum width of the second wiring portion greater than a width of the first wiring portion; and
a first insulating layer having air gaps disposed between the plurality of first wirings.

11. The semiconductor device according to claim 10,
further comprising a barrier layer disposed on side surfaces of the plurality of first wirings,
wherein the barrier layer comprises:
a first barrier portion disposed on a side surface of the first wiring portion; and
a second barrier portion disposed on a side surface of the second wiring portion, and
wherein the second barrier portion protrudes farther in a first direction than the first barrier portion.

12. The semiconductor device according to claim 10,
wherein a lower surface of the first insulating layer is planar.

13. The semiconductor device according to claim 10,
further comprising: a plurality of spacers disposed on side surfaces of the plurality of first wirings,
wherein the plurality of spacers comprises:
a first spacer portion; and
a second spacer portion continuous with the first spacer portion, and
wherein the second spacer portion has a variable width, and a maximum width of the second spacer portion is less than a width of the first spacer portion.

14. A method of manufacturing a semiconductor device, the method comprising:
forming a plurality of first trenches in a second insulating layer on a first substrate;
forming a plurality of spacers on side surfaces of the plurality of first trenches, respectively;
forming a plurality of first wirings in the plurality of first trenches, respectively;
removing the second insulating layer; and
forming a first insulating layer having air gaps formed in regions between the plurality of spacers.

15. The method of claim 14, further comprising:
forming the first insulating layer to cover side surfaces of each of the plurality of spacers and lower surfaces of each of the plurality of first wirings.

16. The method of claim 14, further comprising:
forming the first insulating layer to not be in contact with a portion of a lower surface of the first substrate.

17. The method of claim 14,
wherein each of the plurality of spacers comprises:
a first spacer portion; and
a second spacer portion continuous with the first spacer portion, and
wherein the second spacer portion has a variable width, and a maximum width of the second spacer portion is less than a width of the first spacer portion.

18. The method of claim 14,
wherein each of the plurality of first wirings comprises:
a first wiring portion; and
a second wiring portion continuous with the first wiring portion, and
wherein the second wiring portion has a variable width, and a maximum width of the second wiring portion is greater than a width of the first wiring portion.

19. The method of claim 14, wherein the forming of the first insulating layer further comprises:
depositing an insulating material between the plurality of first wirings, and
planarizing an upper portion of the insulating material.

20. The method of claim 14, wherein the forming of the plurality of spacers further comprises:
forming a barrier layer,
wherein the barrier layer comprises a first barrier portion and a second barrier portion continuous with the first barrier portion, and
wherein the second barrier portion protrudes farther in a first direction than the first barrier portion.
